(19) United States
(12) Patent Application Publication
(10) Pub. No.: US 2017/0226302 A1
(43) Pub. Date: Aug. 10, 2017

(54) CURABLE COMPOSITION, PREPREG, METAL FOIL WITH RESIN, METAL-CLAD LAMINATE AND PRINTED WIRING BOARD

(71) Applicant: Panasonic Intellectual Property Management Co., Ltd., Osaka (JP)

(72) Inventors: HIROSUKE SAITO, Osaka (JP); HIROAKI FUJIWARA, Nara (JP); SAKI NAKADA, Saitama (JP)

(21) Appl. No.: 15/502,930

(22) PCT Filed: Sep. 8, 2015
(86) PCT No.: PCT/JP2015/004541

§ 371 Date: Feb. 9, 2017

(30) Foreign Application Priority Data
Sep. 9, 2014 (JP) 2014-183244

(51) Int. Cl. C08J 5/24; C08K 3/22; C08K 5/52; C08K 5/17; H05K 1/03; C08K 5/01; C08K 5/12; B32B 5/26; B32B 15/14; B32B 15/20; C08K 3/36; C08K 5/3492

(52) U.S. Cl. CPC C08J 5/24; C08K 3/36; C08K 3/22; C08K 5/52; C08K 5/175; C08K 5/34924; C08K 5/01; C08K 5/12; B32B 5/26; B32B 15/14; B32B 15/20; H05K 1/0373; H05K 1/0366; C08K 2003/2227; C08J 2309/00; C08J 2309/06; C08J 2325/10; C08J 2329/10; B32B 2260/023; B32B 2260/046; B32B 2262/101; B32B 2307/206; B32B 2307/202; B32B 2457/08; H05K 2201/0137

(57) ABSTRACT

A curable composition including a radically polymerizable compound containing an unsaturated bond within the molecule, an inorganic filler containing a metal oxide, and a dispersant containing an acidic group and a basic group. The content of the metal oxide is between 80 parts by mass and 100 parts by mass (inclusive) relative to the amount of the inorganic filler of 100 parts by mass. Components of the curable composition other than the inorganic filler are organic components. A content of the inorganic filler is between 80 parts by mass and 400 parts by mass (inclusive) relative to the amount of the organic components of 100 parts by mass. A content of the dispersant is between 0.1 part by mass and 5 parts by mass (inclusive) relative to the amount of the inorganic filler of 100 parts by mass.

### TECHNICAL FIELD

The present disclosure relates to a curable composition, a prepreg, a metal foil with resin, a metal-clad laminate, and a printed wiring board.

### BACKGROUND

In recent years, the quantity of information to be processed has been increasing. Along with this trend, rapidly advancing are the techniques for fabricating semiconductor devices to be mounted in various electronic devices, including a technique for enhancing integration, a technique for enhancing wiring density, and a technique related to multi-layering. For printed wiring boards used in various electronic devices, higher signal transmission rates are demanded. To fulfill this demand, it is required to lower signal transmission loss. Low signal transmission loss can be achieved by using a material that has a low dielectric constant and a low dissipation factor as a substrate material for an insulating layer in a printed wiring board.

Epoxy resin is a material excellent in heat resistance, among other properties, and is widely used. When the epoxy resin cures, polar groups such as a hydroxy group and ester groups are formed. Therefore, an insulating layer produced from the epoxy resin is less likely to have excellent dielectric properties that are a low dielectric constant and a low dissipation factor. Instead of the epoxy resin which has poor dielectric properties after curing, compositions cured by radical polymerization can be used as a substrate material. When such compositions cured by radical polymerization are used, polar groups are less likely to be newly formed upon curing.

In order to suppress an increase in the dielectric constant and the dissipation factor of a printed wiring board and to concurrently suppress warpage of an insulating layer because of thermal expansion thereof, a resin composition containing an inorganic filler can be used as a material for the insulating layer in the printed wiring board. To enhance dispersibility of the inorganic filler, a dispersant can be added to the resin composition containing an inorganic filler.

Examples of the resin composition containing an inorganic filler and a dispersant include the resin composition described in PTL 1.

PTL 1 describes a resin composition that includes a polyarylene ether copolymer, an epoxy resin, a curing accelerator, an inorganic filler, and a dispersant containing a phosphate group within the molecule.

### CITATION LIST

### Patent Literature

PTL 1: Unexamined Japanese Patent Publication No. 2012-197361

### SUMMARY

The present disclosure provides a curable composition that can suitably produce a cured product having excellent dielectric properties, excellent heat resistance, and low thermal expansion. The present disclosure also provides a prepreg, a metal foil with resin, a metal-clad laminate, and a printed wiring board that are obtained by using the curable composition.

A curable composition according to an exemplary aspect of the present disclosure includes a radically polymerizable compound containing an unsaturated bond within the molecule, an inorganic filler containing a metal oxide, and a dispersant containing an acidic group and a basic group. The content of the metal oxide is between 80 parts by mass and 100 parts by mass (inclusive) relative to an amount of the inorganic filler of 100 parts by mass. Components of the curable composition other than the inorganic filler are organic components. A content of the inorganic filler is between 80 parts by mass and 400 parts by mass (inclusive) relative to the amount of the organic components of 100 parts by mass. A content of the dispersant is between 0.1 part by mass and 5 parts by mass (inclusive) relative to the amount of the inorganic filler of 100 parts by mass.

The present disclosure can provide a curable composition that can suitably produce a cured product having excellent dielectric properties, excellent heat resistance, and low thermal expansion. The present disclosure also provides a prepreg, a metal foil with resin, a metal-clad laminate, and a printed wiring board that are obtained by using the curable composition.

### BRIEF DESCRIPTION OF DRAWINGS

FIG. 1 is a sectional view of a prepreg according to an exemplary embodiment of the present disclosure.

FIG. 2 is a sectional view of a metal-clad laminate according to the exemplary embodiment of the present disclosure.

FIG. 3 is a sectional view of a printed wiring board according to the exemplary embodiment of the present disclosure.

FIG. 4 is a sectional view of a metal foil with resin according to the exemplary embodiment of the present disclosure.

### DESCRIPTION OF EMBODIMENT

Before describing an exemplary embodiment of the present disclosure, problems of conventional printed wiring boards are described.

PTL 1 discloses a resin composition that has excellent dielectric properties attributed to a polyarylene ether copolymer contained therein. PTL 1 also discloses that the cured product of the resin composition is excellent in formability, heat resistance, and flame retardancy.

There are demands for printed wiring boards not only to have low signal transmission loss to achieve an enhanced signal transmission rate but also to have enhanced heat resistance and lowered thermal expansion. To satisfy these demands, a new material is sought after for use for an insulating layer of a printed wiring board.

The inventors of the present disclosure have focused on the use of a composition that cured by radical polymerization, as described above, to replace epoxy resin. The inventors of the present disclosure have considered addition of an inorganic filler in a relatively high amount to a radically polymerizable composition for the purpose of enhancing heat resistance, among other properties, of the resulting cured product. When an inorganic filler is added in a high amount, however, flowability of the curable composition may decrease. As a result of the decreased flowability of the curable composition, the resulting cured product may have insufficient formability, such as formation of void in the resulting cured product.

The flowability of the curable composition can be enhanced by lowering the molecular weight of the organic components and consequently lowering the viscosity of the organic components. When the viscosity of the organic components is lowered, however, the organic components may ooze from the curable composition during the forming process of the curable composition. When the organic components thus ooze, the organic components may separate in the curable composition and, as a result, formability of the resulting cured product may be insufficient.

As another method for enhancing flowability of the curable composition, addition of a dispersant such as the one described in PTL 1 to the organic components is considered. When the dispersant is added, however, the resulting cured product may have insufficient heat resistance.

The dispersant described in PTL 1 contains a phosphate group within the molecule. It is considered that this phosphate group provides for the ability of the dispersant to stabilize radicals in the composition and to inhibit radical polymerization from occurring. It is also considered that this inhibition of radical polymerization causes the insufficient heat resistance, among other properties, of the resulting cured product.

The inventors of the present disclosure have further studied. The inventors of the present disclosure have focused on the compositions, or structures, of an inorganic filler and a dispersant and, as a result, have invented a curable composition described below.

The present exemplary embodiment will be described below. The scope of the present disclosure, however, is not limited to the present exemplary embodiment.

A curable composition according to the exemplary embodiment of the present disclosure includes a radically polymerizable compound containing an unsaturated bond within the molecule, an inorganic filler containing a metal oxide, and a dispersant containing an acidic group and a basic group.

The content of the metal oxide is between 80 parts by mass and 100 parts by mass (inclusive) relative to an amount of the inorganic filler of 100 parts by mass. In other words, the curable composition includes the inorganic filler that contains the metal oxide in a content between 80% by mass and 100% by mass (inclusive).

The metal oxide has no hydroxy group or the like that can deteriorate dielectric properties. It is considered that when containing such a metal oxide in the relatively high amount described above, the inorganic filler can suppress deterioration in dielectric properties, enhance heat resistance of the cured product, and lower thermal expansion of the cured product.

When components of the curable composition other than the inorganic filler are referred to as organic components, the content of the inorganic filler is between 80 parts by mass and 400 parts by mass (inclusive) relative to an amount of the organic components of 100 parts by mass. It is considered that when containing the inorganic filler in the relatively high amount described above, the curable composition produces a cured product having excellent dielectric properties, excellent heat resistance, and low thermal expansion. The organic components herein are components of the curable composition other than the inorganic filler.

The content of the dispersant in the curable composition is between 0.1 part by mass and 5 parts by mass (inclusive) relative to the amount of the inorganic filler of 100 parts by mass.

The dispersant contains both an acidic group and a basic group. It is considered that such a dispersant is capable of not only enhancing dispersibility of the inorganic filler but also, because of the presence of the basic group, inhibiting radicals in the composition from being stabilized by the acidic group and consequently allowing radical polymerization to suitably proceed. It is considered that when the dispersant is contained in the content described above, the dispersant can suitably disperse the inorganic filler that is contained in the relatively high amount described above and can also sufficiently suppress the inhibition of polymerization of the radically polymerizable compound. It is considered that because the inhibition is thus suppressed, polymerization of the radically polymerizable compound can suitably proceed, the resulting cured product produced by polymerization and curing has no polar groups such as hydroxy group that are newly formed and, as a result, the cured product can have excellent dielectric properties. It is considered that because the inorganic filler is thus suitably dispersed within the cured product, excellent heat resistance and low thermal expansion can be obtained in addition to the excellent dielectric properties.

Thus, by using the curable composition, a cured product having excellent dielectric properties, excellent heat resistance, and low thermal expansion can be suitably produced. By using the curable composition to form an insulating layer and then fabricate a printed wiring board, an excellent printed wiring board can be obtained.

The curable composition cured by radical polymerization. The curable composition, compared to a thermosetting resin such as an epoxy resin composition, is advantageous in its short curing time. It should be noted, however, that this short curing time leads to insufficient formability of the curable composition when the curable composition includes the inorganic filler in a high amount. When the composition cured by radical polymerization is used, a fibrous base material such as glass cloth is excellently impregnated with it, compared to the case when impregnated with a thermosetting resin such as an epoxy resin composition.

The radically polymerizable compound according to the present exemplary embodiment is not particularly limited provided that it contains an unsaturated bond within the molecule, in other words, it contains a radically polymerizable unsaturated group within the molecule. Examples of the radically polymerizable compound include butadiene polymers such as polybutadiene, butadiene-styrene copolymers, acrylonitrile-butadiene copolymers, and acrylonitrile-butadiene-styrene copolymers, vinyl ester resins such as a reaction product of an epoxy resin and acrylic acid, methacrylic acid, or other unsaturated fatty acid, unsaturated polyester resins, and modified polyphenylene ethers having a terminal functional group containing an unsaturated bond. Among these, the radically polymerizable compound is preferably polybutadiene, a butadiene-styrene copolymer, or a modified polyphenylene ether and is more preferably a modified polyphenylene ether. When a modified polyphenylene ether is used as the radically polymerizable compound, the cured product has excellent dielectric properties and a high glass transition temperature, Tg, and the curable composition has further improved heat resistance. As the radically polymerizable compound, these compounds may be used alone or as a combination of two or more of these.

The modified polyphenylene ether is not particularly limited provided that it has a terminal functional group containing an unsaturated bond. The functional group containing the unsaturated bond is formed by, for example, modification of a terminus of the polyphenylene ether molecule. Examples of the unsaturated bond include a carbon-carbon unsaturated bond. Examples of the carbon-carbon unsaturated bond include a carbon-carbon double bond.

A substituent containing the carbon-carbon unsaturated bond is not particularly limited. Examples of the substituent include a substituent of formula (1).

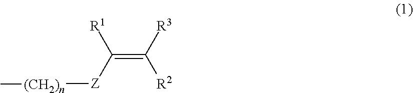

In formula (1), n is an integer between 0 and 10 (inclusive), Z is an arylene group, R1 to R3 are independent of each other, in other words, R1 to R3 may be the same as or different from each other, and R1 to R3 are each a hydrogen atom or an alkyl group.

In formula (1), when n is 0, Z is directly bonded to a terminus of the polyphenylene ether molecule.

The arylene group is not particularly limited. Specific examples of the arylene group include monocyclic aromatic groups such as phenylene group, and polycyclic aromatic groups in which its aromatic ring or rings are not monocyclic aromatic rings but polycyclic aromatic rings such as a naphthalene ring. Examples of the arylene group include derivatives of the arylene group in which a hydrogen atom bonded to the aromatic ring is replaced by a functional group such as an alkenyl group, an alkynyl group, a formyl group, an alkylcarbonyl group, an alkenylcarbonyl group, or an alkynylcarbonyl group. The alkyl group is not particularly limited either. For example, the alkyl group contains carbon atom(s) preferably in a number between 1 and 18 (inclusive) and more preferably in a number between 1 and 10 (inclusive). Specific examples of the alkyl group include methyl group, ethyl group, propyl group, hexyl group, and decyl group.

Specific examples of the substituent include vinylbenzyl groups (ethenylbenzyl groups) such as p-ethenylbenzyl group and m-ethenylbenzyl group and vinylphenyl groups.

Specific examples of the functional group having a vinylbenzyl group, in particular, include at least one substituent selected from a group of formula (2) and a group of formula (3).

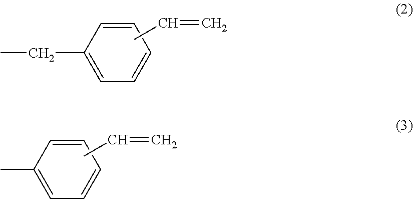

Regarding the modified polyphenylene ether according to the present exemplary embodiment, additional examples of the substituent that has a modified terminus and a carbon-carbon unsaturated bond include acrylate group and methacrylate group. Such a substituent is represented by formula (4), for example.

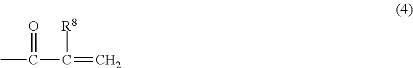

In formula (4), R8 is a hydrogen atom or an alkyl group. The alkyl group is not particularly limited. For example, the alkyl group contains carbon atom(s) preferably in a number between 1 and 18 (inclusive) and more preferably in a number between 1 and 10 (inclusive). Specific examples of the alkyl group include methyl group, ethyl group, propyl group, hexyl group, and decyl group.

In terms of reactivity, the substituent is preferably a vinyl group or a methacrylate group (a methacrylic group). In other words, both a vinyl group and a methacrylate group (a methacrylic group) have preferable reactivity, which is higher than the reactivity of an allyl group and lower than the reactivity of an acrylic group.

The modified polyphenylene ether contains a polyphenylene ether chain within the molecule. For example, the modified polyphenylene ether preferably contains a repeating unit of formula (5) within the molecule.

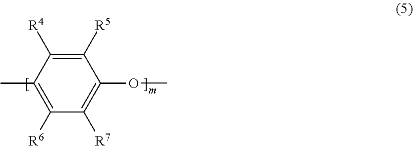

In formula (5), m is an integer between 1 and 50 (inclusive), R4 to R7 are independent of each other, in other words, R4 to R7 may be the same as or different from each other, R4 to R7 are each a hydrogen atom, an alkyl group, an alkenyl group, an alkynyl group, a formyl group, an alkylcarbonyl group, an alkenylcarbonyl group, or an alkynylcarbonyl group. Preferably, R4 to R7 are each a hydrogen atom or an alkyl group, among others.

Specific examples of R4 to R7 include the following functional groups.

The alkyl group is not particularly limited. For example, the alkyl group contains carbon atom(s) in a number preferably between 1 and 18 (inclusive) and more preferably between 1 and 10 (inclusive). Specific examples of the alkyl group include methyl group, ethyl group, propyl group, hexyl group, and decyl group.

The alkenyl group is not particularly limited. For example, the alkenyl group contains carbon atom(s) in a number preferably between 2 and 18 (inclusive) and more preferably between 2 and 10 (inclusive). Specific examples of the alkenyl group include vinyl group, allyl group, and 3-butenyl group.

The alkynyl group is not particularly limited. For example, the alkynyl group contains carbon atom(s) in a number preferably between 2 and 18 (inclusive) and more preferably between 2 and 10 (inclusive). Specific examples of the alkynyl group include ethynyl group and prop-2-yn-1-yl group (propargyl group).

The alkylcarbonyl group is not particularly limited provided that it is a carbonyl group substituted with an alkyl group. For example, the alkylcarbonyl group contains carbon atom(s) in a number preferably between 2 and 18 (inclusive) and more preferably between 2 and 10 (inclusive). Specific examples of the alkylcarbonyl group include acetyl group, propionyl group, butyryl group, isobutyryl group, pivaloyl group, hexanoyl group, octanoyl group, and cyclohexylcarbonyl group.

The alkenylcarbonyl group is not particularly limited provided that it is a carbonyl group substituted with an alkenyl group. For example, the alkenylcarbonyl group contains carbon atom(s) in a number preferably between 3 and 18 (inclusive) and more preferably between 3 and 10 (inclusive). Specific examples of the alkenylcarbonyl group include acryloyl group, methacryloyl group, and crotonoyl group.

The alkynylcarbonyl group is not particularly limited provided that it is a carbonyl group substituted with an alkynyl group. For example, the alkynylcarbonyl group contains carbon atom(s) in a number preferably between 3 and 18 (inclusive) and more preferably between 3 and 10 (inclusive). Specific examples of the alkynylcarbonyl group include propioloyl group.

The modified polyphenylene ether is not particularly limited in terms of the weight average molecular weight (Mw). Specifically, the weight average molecular weight (Mw) of the modified polyphenylene ether is preferably between 500 and 5000 (inclusive), more preferably between 500 and 2000 (inclusive), and further preferably between 1000 and 2000 (inclusive). The Mw is simply required to be measured by a method typically employed for measuring molecular weight. Specific examples of the method include gel permeation chromatography (GPC). When the modified polyphenylene ether contains the repeating unit of formula (2) within the molecule, m is preferably a numerical value that makes the Mw of the modified polyphenylene ether fall within the range described above. Specifically, m is preferably between 1 and 50 (inclusive).

When the Mw of the modified polyphenylene ether is within the range described above, the cured product of the curable composition has excellent dielectric properties attributed to polyphenylene ether and also has further excellent heat resistance and excellent formability. The reason for this phenomenon is considered as follows. Compared to the case where a typical polyphenylene ether having Mw within the range described above tends to produce a cured product having low heat resistance, which is attributed to the relatively low Mw, the modified polyphenylene ether produces a cured product having sufficiently high heat resistance, which is attributed to the one or more terminal unsaturated bonds contained in the modified polyphenylene ether. In addition, when the Mw of the modified polyphenylene ether is within the range described above, which is relatively low, excellent formability is obtained. In this way, it is considered that use of the modified polyphenylene ether achieves further excellent heat resistance and excellent formability of the cured product.

In the modified polyphenylene ether, the average number of terminal substituents per modified polyphenylene ether molecule (the number of terminal functional groups) is not particularly limited. Specifically, the number of terminal functional groups is preferably between 1 and 5 (inclusive), more preferably between 1 and 3 (inclusive), and further preferably between 1.5 and 3 (inclusive). When the number of terminal functional groups is too small, a sufficient level of heat resistance of the cured product is less likely to be obtained. When the number of terminal functional groups is too great, the reactivity to be obtained is too high. When the reactivity is too high, problems may occur such as low storage stability of the curable composition and low fluidity of the curable composition. In other words, use of the modified polyphenylene ether that contains too many terminal functional groups leads to insufficient fluidity, among others, and may consequently cause defects in formation, such as voids created during multilayer formation. A printed wiring board having these defects is less likely to be reliable, which is a problem in terms of formability.

The number of terminal functional groups in the modified polyphenylene ether compound is, for example, the average number of substituents per modified polyphenylene ether molecule in 1 mol of the modified polyphenylene ether. The number of terminal functional groups can be determined by, for example, counting the number of hydroxy groups remaining in the modified polyphenylene ether obtained and then calculating the decrement in the number of hydroxy groups in the polyphenylene ether before and after modification. This decrement in the number of hydroxy groups in the polyphenylene ether before and after modification is used as the number of terminal functional groups. The number of hydroxy groups remaining in the modified polyphenylene ether can be determined by adding a quaternary ammonium salt associated with a hydroxy group (tetraethylammonium hydroxide) to a solution of the modified polyphenylene ether and then subjecting the resulting mixed solution to UV absorbance measurement.

The modified polyphenylene ether is not particularly limited in terms of intrinsic viscosity. Specifically, the intrinsic viscosity of the modified polyphenylene ether is simply required to be between 0.03 dl/g and 0.12 dl/g (inclusive), preferably between 0.04 dl/g and 0.11 dl/g (inclusive), and further more preferably between 0.06 dl/g and 0.095 dl/g (inclusive). When the intrinsic viscosity is too low, the molecular weight tends to be low. When the molecular weight is low, excellent dielectric properties such as a low dielectric constant and a low dissipation factor tend not to be obtained. When the intrinsic viscosity is too high, sufficient fluidity is not obtained and the formability of the cured product tends to be poor. When the intrinsic viscosity of the modified polyphenylene ether is within the range described above, the heat resistance and the formability of the cured product can be enhanced.

The intrinsic viscosity herein is the value of intrinsic viscosity measured in methylene chloride at 25° C. Specific examples of the intrinsic viscosity value herein include the value of viscosity of a solution (liquid temperature, 25° C.) containing 0.18 g of the modified polyphenylene ether as a specimen mixed in 45 ml of methylene chloride measured with a capillary viscometer. Examples of the viscometer used herein include an AVS500 Visco System manufactured by Schott.

The inorganic filler according to the present exemplary embodiment is not particularly limited provided that it contains the metal oxide in an amount between 80% by mass and 100% by mass (inclusive). In other words, the content of the metal oxide is simply required to be not lower than 80 parts by mass and is preferably between 90 parts by mass and 100 parts by mass (inclusive) relative to the amount of the inorganic filler of 100 parts by mass. The inorganic filler is simply required to contain the metal oxide in an amount of not lower than 80% by mass, and may be the metal oxide itself. When an additional inorganic filler other than the metal oxide, such as a metal hydroxide, is contained, the content of the additional inorganic filler other than the metal oxide is lower than 20% by mass. When the content of the metal oxide is too low, the content of the metal hydroxide is relatively high, for example, resulting in a tendency toward poor dielectric properties

The inorganic filler such as the metal oxide is not particularly limited and examples of the inorganic filler include a substance that is added for enhancing heat resistance and flame retardancy of the cured product of a curable composition. When the curable composition includes polyphenylene ether, the curable composition has a low crosslink density compared to, for example, a cured product of a typical epoxy resin composition used in an insulating base material, and the coefficient of thermal expansion of such a cured product tends to be high and, in particular, the coefficient of thermal expansion of the cured product at a temperature higher than the glass transition temperature, referred to as the coefficient of thermal expansion α2, tends to be high. When the inorganic filler is contained, however, dielectric properties are enhanced and the heat resistance and the flame retardancy of the cured product are also enhanced. In addition, when the inorganic filler is contained, the coefficient of thermal expansion of the cured product is low and, in particular, the coefficient of thermal expansion of the cured product at a temperature higher than the glass transition temperature, referred to as the coefficient of thermal expansion α2, is low with the varnish viscosity being maintained low, rendering the cured product strong and tough.

Specific examples of the metal oxide include silicas such as crushed silica and spherical silica, alumina, magnesium oxide, and titanium oxide. Among these, silicas are preferable and spherical silica is particularly preferable. Silicas are preferable because they have a preferable dielectric constant compared to alumina the dielectric constant of which tends to be too high. In terms of enhancement in the flowability of the curable composition, spherical silica is preferable. As the metal oxide, these oxides may be used alone or as a combination of two or more of these. An additional inorganic filler other than the metal oxide may also be contained. Specific examples of the additional inorganic filler other than the metal oxide include metal hydroxides such as talc, aluminum hydroxide, and magnesium hydroxide, mica, aluminum borate, barium sulfate, and calcium carbonate.

The inorganic filler may be used as it is. Alternatively, the inorganic filler may be subjected to surface treatment with the use of, for example, a silane coupling agent. Examples of the silane coupling agent include vinylsilane, styrylsilane, methacrylsilane, acrylsilane, epoxysilane, aminosilane, mercaptosilane, isocyanate silane, alkylsilanes, and isocyanurate silane. Among these, vinylsilane, styrylsilane, methacrylsilane, and acrylsilane are preferable in terms of their affinity with the radically polymerizable compound and in terms of adhesion and electrical properties of the resulting cured product. The silane coupling agent may be used in this way in preliminary surface treatment of the inorganic filler, or may be added by the integral blending method.

The content of the inorganic filler is between 80 parts by mass and 400 parts by mass (inclusive), preferably between 100 parts by mass and 350 parts by mass (inclusive), and more preferably between 150 parts by mass and 250 parts by mass (inclusive) relative to the amount of the organic components of 100 parts by mass. When the content of the inorganic filler is too low, the effects achievable by the inorganic filler, such as improvement in the heat resistance and the flame retardancy of the cured product, cannot be obtained nor does the thermal expansion of the cured product tend to be sufficiently lowered. When the content of the inorganic filler is too high, the content of components other than the inorganic filler, such as the content of the organic components, is too low. Lack of the organic components tends to result in poor formability of the cured product. Even when a dispersant is added as described below for enhancing dispersibility, sufficient dispersibility is less likely to be obtained and, as a result, the flowability of the curable composition tends to be insufficient. When the content of the inorganic filler is within the range described above, a resin composition that produces a cured product further excellent in formability and heat resistance can be obtained. The organic components herein are components other than the inorganic component contained in the curable composition, in other words, other than the inorganic filler. Specific examples of the organic components include a radically polymerizable compound, a dispersant, a crosslinking agent, and a reaction initiator.

The dispersant according to the present exemplary embodiment contains an acidic group and a basic group. In other words, the dispersant according to the present exemplary embodiment is not particularly limited provided that it is an amphoteric dispersant. The dispersant may contain both an acidic group and a basic group within one molecule, or may contain a molecule having an acidic group and a molecule having a basic group. As long as containing both an acidic group and a basic group, the dispersant may also contain other functional groups. Examples of the other functional groups include hydrophilic functional groups such as hydroxy group.

Examples of the acidic group include carboxy group, acid anhydride group, sulfonic group (sulfo group), thiol group, phosphate group, acidic phosphoric acid ester group, hydroxy group, and phosphonic acid group. Among these acidic groups, phosphate group, carboxy group, hydroxy group, and sulfo group are preferable, and phosphate group and carboxy group are more preferable.

Examples of the basic group include amino group, imino group, ammonium salt group, imidazoline group, pyrrole group, imidazole group, benzimidazole group, pyrazole group, pyridine group, pyrimidine group, pyrazine group, pyrrolidine group, piperidine group, piperazine group, indole group, indoline group, purine group, quinoline group, isoquinoline group, quinuclidine group, and triazine group. Among these, amino group, imidazoline group, ammonium salt group, pyrrole group, imidazole group, benzimidazole group, pyrazole group, pyridine group, pyrimidine group, pyrazine group, pyrrolidine group, piperidine group, piperazine group, indole group, indoline group, purine group, quinoline group, isoquinoline group, quinuclidine group, and triazine group are preferable and amino group and imidazoline group are more preferable. Examples of the ammonium salt group include alkylol ammonium salt group.

The dispersant may contain, as the acidic group, one, two, or more acidic groups listed above, and the dispersant may contain, as the basic group, one, two, or more basic groups listed above.

Specifically, the dispersant is preferably a dispersant containing a phosphate group and an imidazoline group or a dispersant containing a carboxy group and an amino group. Examples of the dispersant containing a phosphate group and an imidazoline group include BYK-W969 manufactured by BYK Japan KK. Examples of the dispersant containing a carboxy group and an amino group include BYK-W966 manufactured by BYK Japan KK.

The acid value of the dispersant is preferably between 30 mg KOH/g and 150 mg KOH/g (inclusive) and more preferably between 30 mg KOH/g and 100 mg KOH/g (inclusive) in terms of the solid content. When the acid value is too low, the dispersibility of the inorganic filler cannot be sufficiently enhanced and, as a result, formability tends to be poor. When the acid value is too high, there is a tendency that the cured product has poor heat resistance, such as a low Tg, poor adhesive force, and poor electrical properties. The acid value is an acid value per 1 g of the dispersant solid. The acid value is measured by potentiometric titration in conformity with DIN EN ISO 2114.

The amine value of the dispersant is preferably between 30 mg KOH/g and 150 mg KOH/g (inclusive) and more preferably between 30 mg KOH/g and 100 mg KOH/g (inclusive) in terms of the solid content. More preferably, the amine value is substantially the same as the acid value. When the amine value is too low relative to the acid value, the influence of the acid value is exhibited excessively. In this case, the radical curing system is adversely affected and, as a result, the cured product tends to have poor heat resistance, such as a low Tg, poor adhesive force, and poor electrical properties. When the amine value is too high relative to the acid value, the influence of the amine value is exhibited excessively and this great influence tends to cause low dispersibility and consequent poor formability, and poor electrical properties of the cured product. The amine value is an amine value per 1 g of the dispersant solid. The amine value is measured by potentiometric titration in conformity with DIN16945 in which a 0.1-N HClO₄ acetic acid aqueous solution is used.

The content of the dispersant is between 0.1 part by mass and 5 parts by mass (inclusive), preferably between 0.3 part by mass and 3 parts by mass (inclusive), and more preferably between 0.5 part by mass and 2 parts by mass (inclusive) relative to the amount of the inorganic filler of 100 parts by mass. When the content of the dispersant is too low, formability of the curable composition tends to be poor. The reason for such poor formability is considered that the effect of the dispersant to enhance dispersibility of the inorganic filler in the organic components is not sufficiently exhibited. On the other hand, when the content of the dispersant is too high, there is a tendency that heat resistance of the cured product cannot be sufficiently enhanced. The reason for this tendency is considered that the dispersant contains both an acidic group and a basic group and therefore too much of the dispersant leads to too high moisture absorption. Therefore, when the content of the dispersant is within the range, the resin composition can produce a cured product further excellent in formability and heat resistance.

The resin composition according to the present exemplary embodiment may also adopt a composition, or a structure, that is different from the one described above composed of the radically polymerizable compound, the inorganic filler, and the dispersant, provided that the desired properties to be provided by the present disclosure are not deteriorated. Specific examples of the composition or structure include the following.

The curable composition according to the present exemplary embodiment may include a crosslinking agent containing an unsaturated bond within the molecule. When the curable composition includes the crosslinking agent, the resulting cured product has a high glass transition temperature and excellent heat resistance. The reason for this phenomenon is considered that the crosslinking agent strengthens the crosslinked structure of the cured product. The crosslinking agent is not particularly limited provided that it contains a carbon-carbon unsaturated bond within the molecule. In other words, the crosslinking agent is simply required to be capable of reacting with the radically polymerizable compound such as the modified polyphenylene ether and forming crosslinks for curing. The crosslinking agent is preferably a compound that contains two or more carbon-carbon unsaturated bonds within the molecule.

The Mw of the crosslinking agent is preferably between 100 and 5000 (inclusive), more preferably between 100 and 4000 (inclusive), and preferably between 100 and 3000 (inclusive). When the Mw of the crosslinking agent is too low, the crosslinking agent may readily volatilize from the system of the curable composition. When the Mw of the crosslinking agent is too high, the viscosity of the curable composition may be too high and the melt viscosity of the curable composition during thermoforming may be too high. For these reasons, when the Mw of the crosslinking agent is within the range described above, the curable composition produces a cured product further excellent in heat resistance. The reason for this phenomenon is considered that reaction of the crosslinking agent with the radically polymerizable compound such as the modified polyphenylene ether can suitably form crosslinks. The Mw here is simply required to be measured by a method typically employed for measuring molecular weight. Specific examples of the method include gel permeation chromatography (GPC).

Depending, for example, on the Mw of the crosslinking agent, the average number of carbon-carbon unsaturated bonds per molecule of the crosslinking agent (the number of terminal double bonds) varies. The number of terminal double bonds is preferably between 1 and 20 (inclusive), for example, and is more preferably between 2 and 18 (inclusive). When the number of terminal double bonds is too small, sufficient heat resistance of the cured product is less likely to be obtained. When the number of terminal double bonds is too great, reactivity to be obtained is too high. In this case, problems may occur such as low storage stability of the curable composition and low fluidity of the curable composition and, as a result, formability of the cured product may be poor.

When the Mw of the crosslinking agent is lower than 500 (for example, between 100 and 500 (inclusive)), the number of terminal double bonds of the crosslinking agent is preferably between 1 and 4 (inclusive), and when the Mw of the crosslinking agent is not lower than 500 (for example, between 500 and 5000 (inclusive)), the number of terminal double bonds of the crosslinking agent is preferably between 3 and 20 (inclusive). In either case, when the number of terminal double bonds is smaller than the lower limit, reactivity of the crosslinking agent may be low and because of this low reactivity, the crosslink density in the cured product of the curable composition may be low and therefore heat resistance and Tg may not be sufficiently improved. When the number of terminal double bonds is greater than the upper limit, on the other hand, gelation of the curable composition may be facilitated.

The number of terminal double bonds can be known from the product spec of the crosslinking agent. Specific examples of the number of terminal double bonds include the average number of double bonds per crosslinking agent molecule in 1 mol of the crosslinking agent.

Specific examples of the crosslinking agent include trialkenyl isocyanurate compounds such as triallyl isocyanurate (TAIC), polyfunctional methacrylate compounds having two or more methacrylic groups within the molecule, polyfunctional acrylate compounds having two or more acrylic groups within the molecule, vinyl compounds having two or more vinyl groups within the molecule (polyfunctional vinyl compounds) such as polybutadiene and butadiene-styrene copolymers, allyl compounds having two or more allyl groups within the molecule (polyfunctional allyl compounds) such as diallyl phthalate (DAP), and vinylbenzyl compounds having a vinylbenzyl group within the molecule such as styrene and divinylbenzene. Preferable among these are ones having two or more carbon-carbon double bonds within the molecule. Specific examples include trialkenyl isocyanurate compounds, polyfunctional acrylate compounds, polyfunctional methacrylate compounds, polyfunctional vinyl compounds, and divinylbenzene compounds. It is considered that by using these compounds, crosslinks are more suitably formed by curing reaction and, as a result, heat resistance of the cured product of the curable composition according to the present exemplary embodiment can be further enhanced. As the crosslinking agent, these crosslinking agents may be used alone or as a combination of two or more of these. As the crosslinking agent, a compound having two or more carbon-carbon unsaturated bonds within the molecule and a compound having a single carbon-carbon unsaturated bond within the molecule may be used in combination. Specific examples of the compound having a single carbon-carbon unsaturated bond within the molecule include compounds having a single vinyl group within the molecule (monovinyl compounds).

The content of the crosslinking agent is preferably between 10 parts by mass and 70 parts by mass (inclusive) and is more preferably between 10 parts by mass and 50 parts by mass (inclusive) relative to the total amount of the radically polymerizable compound and the crosslinking agent of 100 parts by mass. In other words, the mass ratio between the radically polymerizable compound and the crosslinking agent is preferably from 90:10 to 30:70 and is preferably from 90:10 to 50:50. When both the content of the radically polymerizable compound and the content of the crosslinking agent satisfy the ratios above, the resin composition produces a cured product further excellent in heat resistance and flame retardancy. The reason for this phenomenon is considered that the curing reaction between the radically polymerizable compound and the crosslinking agent proceeds suitably.

The curable composition according to the present exemplary embodiment may include the reaction initiator. Even when no reaction initiator is contained in the curable composition, polymerization reaction (curing reaction) of the radically polymerizable compound can proceed. However, raising temperature high enough for the curing reaction to proceed is sometimes difficult depending on the process conditions, and therefore the reaction initiator may be added. The reaction initiator is not particularly limited provided that it can facilitate polymerization reaction of the radically polymerizable compound. Examples of the reaction initiator include peroxides. Specific examples of the reaction initiator include α,α′-bis(t-butylperoxy-m-isopropyl)benzene, 2,5-dimethyl-2,5-di(t-butylperoxy)-3-hexyne, benzoyl peroxide, 3,3′,5,5′-tetramethyl-1,4-diphenoquinone, chloranil, 2,4,6-tri-t-butylphenoxyl, t-butylperoxyisopropyl monocarbonate, and azobisisobutyronitrile. As needed, a metal carboxylate, for example, can be used in combination. Such a combination can further facilitate the curing reaction. Among the specific examples of the reaction initiator, α,α′-bis(t-butylperoxy-m-isopropyl)benzene is preferably used. This is because the temperature at which α,α′-bis(t-butylperoxy-m-isopropyl)benzene starts to react is relatively high and, therefore, during a process where curing does not need to proceed such as during prepreg drying, facilitation of curing reaction can be suppressed, leading to a potential suppression of a decrease in storage stability of the curable composition. In addition, α,α′-bis(t-butylperoxy-m-isopropyl)benzene has low volatility and therefore it does not volatilize during prepreg drying and storage and therefore has excellent stability. The reaction initiator may be used alone or as a combination of two or more of these.

The content of the reaction initiator is preferably between 0 part by mass and 10 parts by mass (inclusive) relative to the amount of the organic components of 100 parts by mass. The content of the reaction initiator is preferably between 0.5 part by mass and 5 parts by mass (inclusive) relative to the amount of the organic components of 100 parts by mass. The reaction initiator is not necessary, as described above. However, when the content of the reaction initiator is too low, there is a tendency that the effects to be exhibited by the reaction initiator are not sufficiently exhibited. When the content of the reaction initiator is too high, dielectric properties and heat resistance of the resulting cured product tend to be adversely affected.

The curable composition according to the present exemplary embodiment may include a flame retardant. The flame retardant can further enhance the flame retardancy of the cured product of the curable composition. The flame retardant is not particularly limited. Specifically, in the case where a halogen-based flame retardant such as a bromine-based flame retardant is used, it is preferable to use ethylene dipentabromobenzene, ethylene bistetrabromoimide, decabromodiphenyloxyde, or tetradecabromodiphenoxybenzene, all of which have a melting point of not lower than 300° C. It is considered that use of the halogen-based flame retardant can suppress halogen elimination at high temperatures and can suppress a decrease in heat resistance. In the case where a halogen-free flame retardant is required, a phosphoric-acid-ester-based flame retardant, a phosphazene-based flame retardant, or a phosphinate-based flame retardant is used. Specific examples of the phosphoric-acid-ester-based flame retardant include condensed phosphoric acid esters such as dixylenyl phosphate. Specific examples of the phosphazene-based flame retardant include phenoxyphosphazene. Specific examples of the phosphinate-based flame retardant include metal phosphinates such as aluminum dialkylphosphinate. As the flame retardant, the flame retardants listed above may be used alone or as a combination of two or more of these.

The curable composition according to the present exemplary embodiment may further include additives such as a defoaming agent, an antioxidant, a heat stabilizer, an antistatic agent, an ultraviolet absorber, a dye and a pigment, and a lubricant, as needed, provided that the effects of the present disclosure are not impaired. By using the curable composition according to the present exemplary embodiment, a prepreg, a metal foil with resin, a metal-clad laminate, and a printed wiring board can be obtained, as described below.

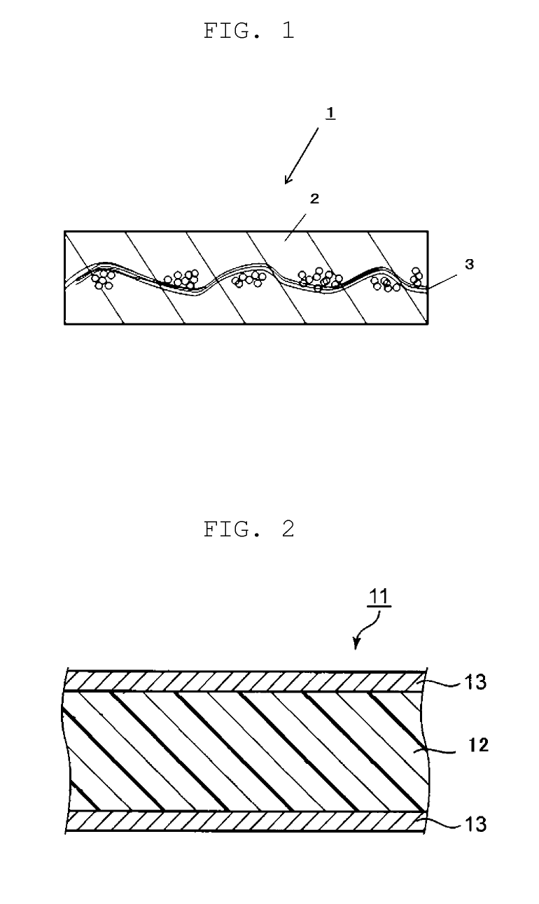

By using the curable composition according to the present exemplary embodiment, a prepreg, a metal foil with resin, a metal-clad laminate, and a printed wiring board can be obtained, as described below. FIG. 1 is a sectional view of the configuration of prepreg 1 according to the present exemplary embodiment.

As shown in FIG. 1, prepreg 1 according to the present exemplary embodiment includes curable composition 2 in an uncured state and fibrous base material 3 impregnated with curable composition 2. In other words, prepreg 1 includes curable composition 2 and fibrous base material 3 impregnated with curable composition 2.

In prepreg production, fibrous base material 3 serving as a base material for prepreg formation is impregnated with curable composition 2. For impregnation, curable composition 2 is usually prepared into varnish. In other words, curable composition 2 is usually a resin varnish, which is curable composition 2 in a varnish form. The resin varnish is prepared as follows, for example.

First, components soluble in organic solvent, such as the radically polymerizable compound and the crosslinking agent, are added to and dissolved in an organic solvent. This procedure may be conducted with heating, as needed. Subsequently, a component that is used as needed and is insoluble in organic solvent, such as the inorganic filler, is added thereto and dispersed therein. Thus, a resin composition varnish is prepared. The dispersion is conducted with the use of a ball mill, a bead mill, a planetary mixer, or a roller mill, for example. The organic solvent used herein is not particularly limited provided that it dissolves the radically polymerizable compound and the crosslinking agent and does not inhibit curing reaction. Specific examples of the organic solvent used herein include toluene and methyl ethyl ketone (MEK).

Examples of the method for prepreg 1 production include a method in which fibrous base material 3 is impregnated with curable composition 2, such as curable composition 2, in a varnish form and then the resultant is dried.

Specific examples of fibrous base material 3 used in prepreg 1 production include glass cloth, aramid cloth, polyester cloth, nonwoven glass fabric, nonwoven aramid fabric, nonwoven polyester fabric, pulp paper, and linter paper. When glass cloth is used, the resulting laminate has excellent mechanical strength. In particular, glass cloth subjected to flattening treatment is preferable. Specific examples of the method of the flattening treatment include continuously applying an appropriate level of pressure to glass cloth with the use of a press a roll so as to compress the yarns flat. The thickness of the fibrous base material that is typically used is between 0.02 mm and 0.3 mm (inclusive), for example.

Fibrous base material 3 is impregnated with curable composition 2 by, for example, immersing fibrous base material 3 in curable composition 2 or applying curable composition 2 to fibrous base material 3. This impregnation step can be repeated a plurality of times, as needed. In this case, the repeated impregnation can be conducted by using a plurality of resin compositions having different compositions in different concentrations so that the desired composition is achieved and the desired amount of curable composition 2 is subjected to impregnation.

Fibrous base material 3 impregnated with curable composition 2 is heated under desired heating conditions, such as a temperature between 80° C. and 180° C. (inclusive) for a duration between 1 minute and 10 minutes (inclusive). By heating, prepreg 1 in a half-cured state (stage B) is obtained.

FIG. 2 is a sectional view of the configuration of metal-clad laminate 11 according to the present exemplary embodiment.

As shown in FIG. 2, metal-clad laminate 11 has insulating layer 12 containing the cured product of prepreg 1 shown in FIG. 1 and metal layer 13 disposed on insulating layer 12. In other words, metal-clad laminate 11 has insulating layer 12 containing the cured product of curable composition 2 and metal layer 13 bonded to insulating layer 12.

Examples of the method for producing metal-clad laminate 11 by using prepreg 1 include a method that covers a single piece or multiple pieces of prepreg 1 with metal layer 13 such as copper foil on both or either of the upper and lower planes of prepreg 1, subjects metal layer 13 and prepreg 1 to heating and pressurization for integration, and, as a result, obtains a laminate that is clad with metal foil on either plane or on one plane. In other words, metal-clad laminate 11 is obtained by laminating prepreg 1 and metal layer 13 together and then subjecting the laminate to heating and pressurization. The conditions during heating and pressurization can be appropriately selected depending on, for example, the thickness of metal-clad laminate 11 to produce and the kind of the prepreg composition. For example, the temperature can be from 170° C. to 210° C., the pressure can be from 1.5 MPa to 5.0 MPa, and the duration can be from 60 minutes to 150 minutes.

Alternatively, metal-clad laminate 11 can be produced by using no prepreg 1 but instead by forming curable composition 2 in a varnish form on metal layer 13 and then subjecting the resultant to heating and pressurization.

By using curable composition 2, a cured product having excellent dielectric properties, excellent heat resistance, and low thermal expansion can be suitably produced. By using prepreg 1 obtained by using curable composition 2, metal-clad laminate 11 having insulating layer 12 having excellent dielectric properties, excellent heat resistance, and low thermal expansion can be produced.

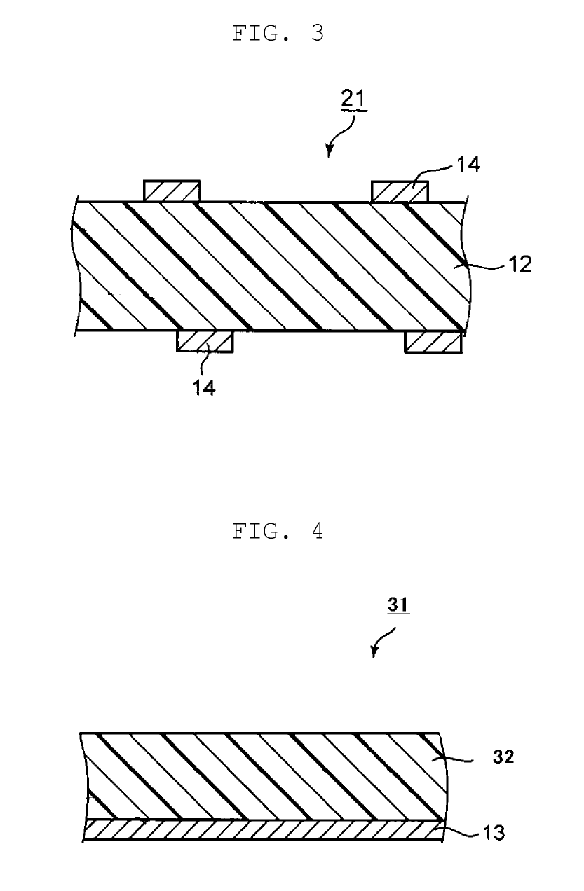

FIG. 3 is a sectional view of the configuration of printed wiring board 21 according to the exemplary embodiment of the present disclosure.

As shown in FIG. 3, printed wiring board 21 according to the present exemplary embodiment includes insulating layer 12 obtained by curing prepreg 1 shown in FIG. 1 and wiring 14 disposed on insulating layer 12. In other words, printed wiring board 21 includes insulating layer 12 containing the cured product of curable composition 2 and wiring 14 bonded to insulating layer 12.

Metal layer 13 on the surface of metal-clad laminate 11 is then subjected to a procedure such as etching to form a wiring. Thus, printed wiring board 21 including the wiring that is disposed on the surface of insulating layer 12 and is to serve as a circuit is obtained. In other words, printed wiring board 21 is obtained by partly removing metal layer 13 on the surface of metal-clad laminate 11 and forming a circuit. Printed wiring board 21 includes insulating layer 12 having excellent dielectric properties, excellent heat resistance, and low thermal expansion.

FIG. 4 is a sectional view of the configuration of metal foil 31 with resin according to the present exemplary embodiment.

As shown in FIG. 4, metal foil 31 with resin has metal layer 13 and insulating layer 32 disposed on metal layer 13. Insulating layer 32 contains curable composition 2 in an uncured state. In other words, metal foil 31 with resin has metal layer 13 and insulating layer 32 in an uncured state bonded to metal layer 13.

To produce insulating layer 32, the same curable composition and the same curing agent as those used in insulating layer 12 of metal-clad laminate 11 can be used. As metal layer 13, metal layer 13 of metal-clad laminate 11 can be used.

The printed wiring board that is fabricated by using metal foil 31 with resin can be further lowered in signal transmission loss without being deteriorated in adhesion between the wiring and insulating layer 12.

Metal foil 31 with resin is produced by, for example, applying curable composition 2 in a varnish form to metal layer 13 and then heating the resultant. Application of curable composition 2 in a varnish form to metal layer 13 is conducted by using, for example, a bar coater. Curable composition 2 thus applied is heated under conditions, for example, a temperature between 80° C. and 180° C. (inclusive) for a duration between 1 minute and 10 minutes (inclusive). Upon heating, the curable composition is formed as insulating layer 32 in an uncured state on metal layer 13.

As described above, the present specification discloses various technical aspects. Among them, major technical aspects are described below.

A curable composition according to an exemplary aspect of the present disclosure includes a radically polymerizable compound containing an unsaturated bond within the molecule, an inorganic filler containing a metal oxide, and a dispersant containing an acidic group and a basic group. The content of the metal oxide is between 80 parts by mass and 100 parts by mass (inclusive) relative to the amount of the inorganic filler of 100 parts by mass. Components of the curable composition other than the inorganic filler are referred to as organic components. The content of the inorganic filler is between 80 parts by mass and 400 parts by mass (inclusive) relative to the amount of the organic components of 100 parts by mass. The content of the dispersant is between 0.1 part by mass and 5 parts by mass (inclusive) relative to the amount of the inorganic filler of 100 parts by mass.

Having this configuration, the curable composition can suitably produce a cured product that has excellent dielectric properties, excellent heat resistance, and low thermal expansion.

The reason for this phenomenon is considered as follows.

The metal oxide has no hydroxy group or the like that can deteriorate dielectric properties. It is considered that when containing such a metal oxide in a relatively high amount, the inorganic filler can suppress deterioration in dielectric properties, enhance heat resistance of the cured product, and lower thermal expansion of the cured product.

It is considered that when containing the inorganic filler in a relatively high amount, the resulting composition produces a cured product having excellent dielectric properties, excellent heat resistance, and low thermal expansion.

The dispersant contains both an acidic group and a basic group. It is considered that such a dispersant is capable of not only enhancing dispersibility of the inorganic filler but also, because of the presence of the basic group, inhibiting radicals in the composition from being stabilized by the acidic group and consequently allowing radical polymerization to suitably proceed. It is considered that when the dispersant is contained in the content described above, the dispersant can suitably disperse the inorganic filler that is contained in the relatively high amount described above and can also sufficiently suppress the inhibition of polymerization of the radically polymerizable compound. It is considered that because the inhibition is thus suppressed, polymerization of the radically polymerizable compound can suitably proceed, the resulting cured product produced by polymerization and curing has no polar groups such as hydroxy group that are newly formed and, as a result, the cured product can have excellent dielectric properties. It is considered that because the inorganic filler is thus suitably dispersed within the cured product, formability can be improved and excellent heat resistance and low thermal expansion can be obtained in addition to the excellent dielectric properties of the cured product.

Thus, it is considered that the curable composition can suitably produce a cured product having excellent dielectric properties, excellent heat resistance, and low thermal expansion. By using the curable composition to form an insulating layer and then fabricate a printed wiring board, an excellent printed wiring board can be obtained.

In the curable composition, the acidic group is preferably at least one kind selected from the group consisting of phosphate group, carboxy group, hydroxy group, and sulfo group, and the basic group is preferably at least one kind selected from the group consisting of imidazoline group, amino group, ammonium salt group, pyrrole group, imidazole group, benzimidazole group, pyrazole group, pyridine group, pyrimidine group, pyrazine group, pyrrolidine group, piperidine group, piperazine group, indole group, indoline group, purine group, quinoline group, isoquinoline group, quinuclidine group, and triazine group.

Having this configuration, the curable composition can suitably produce a cured product that has further excellent dielectric properties, further excellent heat resistance, and further lowed thermal expansion. By using the curable composition, a further excellent printed wiring board can be fabricated.

Preferably, the dispersant in the curable composition has an acid value between 30 mg KOH/g and 150 mg KOH/g (inclusive) in terms of the solid content. Preferably, the dispersant in the curable composition has an amine value between 30 mg KOH/g and 150 mg KOH/g (inclusive) in terms of the solid content.

Having this configuration, the curable composition can suitably produce a cured product that has further excellent dielectric properties, further excellent heat resistance, and further lowed thermal expansion. By using the curable composition, a further excellent printed wiring board can be fabricated.

Preferably, the curable composition further includes a crosslinking agent containing an unsaturated bond within the molecule.

Having this configuration, the curable composition can suitably produce a cured product that has further excellent dielectric properties, further excellent heat resistance, and further lowed thermal expansion. By using the curable composition, a further excellent printed wiring board can be fabricated.

Preferably, the radically polymerizable compound in the curable composition is a modified polyphenylene ether having a terminal functional group containing an unsaturated bond.

Having this configuration, the curable composition can suitably produce a cured product that has further excellent dielectric properties, further excellent heat resistance, and further lowed thermal expansion. By using the curable composition, a further excellent printed wiring board can be fabricated.

Preferably, the weight average molecular weight of the modified polyphenylene ether in the curable composition is between 500 and 5000 (inclusive). Preferably, the number of functional groups in the modified polyphenylene ether molecule is between 1 and 5 (inclusive) on average within one molecule.

Having this configuration, the curable composition can suitably produce a cured product that has further excellent dielectric properties, further excellent heat resistance, and further lowed thermal expansion. By using the curable composition, a further excellent printed wiring board can be fabricated.

Preferably, the metal oxide in the curable composition is spherical silica.

Having this configuration, the curable composition can suitably produce a cured product that has further excellent dielectric properties, further excellent heat resistance, and further lowed thermal expansion. By using the curable composition, a further excellent printed wiring board can be fabricated.

Preferably, the curable composition further includes a reaction initiator.

Having this configuration, the curable composition can suitably produce a cured product that has further excellent dielectric properties, further excellent heat resistance, and further lowed thermal expansion. By using the curable composition, a further excellent printed wiring board can be fabricated.

A prepreg according to another exemplary aspect of the present disclosure includes the curable composition and a fibrous base material impregnated with the curable composition.

By using the prepreg having this configuration, a metal-clad laminate can be produced that has an insulating layer having excellent formability, excellent dielectric properties, excellent heat resistance, and low thermal expansion.

A metal-clad laminate according to another exemplary aspect of the present disclosure has an insulating layer containing the cured product of the curable composition and a metal layer disposed on the insulating layer.

By using the metal-clad laminate having this configuration, a printed wiring board can be produced that has an insulating layer having excellent dielectric properties, excellent heat resistance, and low thermal expansion.

A printed wiring board according to another exemplary aspect of the present disclosure includes an insulating layer containing the cured product of the curable composition and a wiring disposed on the insulating layer.

The insulating layer in the printed wiring board having this configuration has excellent dielectric properties, excellent heat resistance, and low thermal expansion.

A metal foil with resin according to another exemplary aspect of the present disclosure has a metal layer and an insulating layer disposed on the metal layer, the insulating layer contains the curable composition in an uncured state.

By using the metal foil with resin having this configuration, a printed wiring board can be fabricated that has excellent dielectric properties, excellent heat resistance, and low thermal expansion.

The effects to be obtained by the exemplary embodiment of the present disclosure will be more specifically described by examples. The scope of the present disclosure, however, is not limited to these examples.

### EXAMPLES

### Examples 1 to 15, Comparative Examples 1 to 7

### [Preparation of Curable Composition]

The components used in preparation of a curable composition in the examples are described below.

### (Radically Polymerizable Compound)

As a polybutadiene, Ricon® 150 manufactured by Cray Valley is used.

As a butadiene-styrene copolymer, Ricon®181 manufactured by Cray Valley is used.

As modified polyphenylene ether 1 (modified PPE1), a modified polyphenylene ether in which a terminal hydroxy group of a polyphenylene ether is modified with a vinylbenzyl group (a VB group, an ethenylbenzyl group) is used, which is synthesized in the following way.

Modified PPE1 is obtained by reaction between a polyphenylene ether and chloromethylstyrene. Specifically, modified PPE1 is obtained by the following reaction.

To a 1-liter three-necked flask equipped with a temperature controller, a stirring device, a cooling unit, and a tap funnel, 200 g of polyphenylene ether, 15 g of a mixture of p-chloromethylstyrene and m-chloromethylstyrene at a mass ratio of 50:50, 0.92 g of tetra-n-butylammonium bromide as a phase-transfer catalyst, and 400 g of toluene are added, followed by stirring. The polyphenylene ether is SA120 manufactured by SABIC Innovative Plastics, having a number of terminal hydroxy groups of 1 and a weight average molecular weight, Mw, of 2400. The mixture of p-chloromethylstyrene and m-chloromethylstyrene is chloromethylstyrene (CMS) manufactured by Tokyo Chemical Industry Co., Ltd. Stirring is continued until polyphenylene ether, chloromethylstyrene, and tetra-n-butylammonium bromide are dissolved in toluene. During the stirring, the mixture is gradually heated until the liquid temperature reaches 75° C. To the resulting solution, an aqueous sodium hydroxide solution ((10 g of sodium hydroxide)/(10 g of water)) as an alkali metal hydroxide is added dropwise over 20 minutes. Then, stirring is continued for another 4 hours at 75° C. The content of the flask is neutralized with 10%-by-mass hydrochloric acid, followed by addition of an excess amount of methanol. By the addition, a precipitate is formed in the liquid contained in the flask, in other words, the reaction product precipitates from the reaction mixture in the flask. The precipitate is taken out of the liquid by filtration and is then rinsed three times with a mixed liquid of methanol and water at a mass ratio of 80:20. The resultant is dried under reduced pressure at 80° C. for three hours.

The resulting solid was subjected to 1H-NMR (Nuclear Magnetic Resonance) analysis (400 MHz, CDCl3, TMS). In the NMR analysis, a peak from 5 ppm to 7 ppm attributable to a vinylbenzyl group was observed. Thus, the solid obtained was identified to be a modified polyphenylene ether having a vinylbenzyl group at a molecular terminus, or specifically to be vinylbenzyl polyphenylene ether.

The number of terminal functional groups in the modified polyphenylene ether was measured as follows.

The modified polyphenylene ether was accurately weighed. The weight is assumed to be X (mg). The modified polyphenylene ether thus weighed was dissolved in 25 mL of methylene chloride and to the resulting solution, 100 μL of an ethanol solution containing 10% by mass of tetraethylammonium hydroxide (TEAH) was added. The absorbance (Abs) of the resulting solution at 318 nm was measured with a UV spectrophotometer. The ethanol solution has a volume ratio of TEAH:ethanol=15:85. The UV spectrophotometer is a UV-1600 manufactured by SHIMADZU CORPORATION. Based on the measurement result, the number of terminal hydroxy groups in the modified polyphenylene ether was calculated by using the following formula.

Remaining OH amount (μmol/g)=[(25×Abs)/(ε×OPL×X)]×10⁶

Herein, ε is the absorption coefficient, which is 4700 L/mol·cm, and OPL is the optical path length of the cell, which is 1 cm.

The remaining OH amount (the number of terminal hydroxy groups) in the modified polyphenylene ether thus calculated was near zero, which indicated that almost all the hydroxy groups present in the polyphenylene ether before modification had been subjected to modification. From this result, it is indicated that the decrement in the number of terminal hydroxy groups in the polyphenylene ether before and after modification is the number of terminal hydroxy groups present in the polyphenylene ether before modification. In other words, it is indicated that the number of terminal hydroxy groups present in the polyphenylene ether before modification is the number of terminal functional groups in the modified polyphenylene ether. In other words, the number of terminal functional groups is 1.

The intrinsic viscosity (IV) of the modified polyphenylene ether in methylene chloride at 25° C. was measured. Specifically, the intrinsic viscosity (IV) of the modified polyphenylene ether was measured by subjecting a solution of the modified polyphenylene ether in methylene chloride at a concentration of 0.18 g/45 ml (liquid temperature, 25° C.) to measurement with a viscometer (AVS500 Visco System manufactured by Schott). The intrinsic viscosity (IV) of the modified polyphenylene ether was 0.125 dl/g.

As modified polyphenylene ether 2 (modified PPE2), a modified polyphenylene ether in which a terminal hydroxy group of a polyphenylene ether is modified with a methacrylic group is used. Specifically, modified PPE2 is SA9000 manufactured by SABIC Innovative Plastics, having a weight average molecular weight, Mw, of 1700 and a number of terminal functional groups of 1.8.

As modified polyphenylene ether 3 (modified PPE3), a modified polyphenylene ether in which a terminal hydroxy group of a polyphenylene ether is modified with a vinylbenzyl group (a VB group, an ethenylbenzyl group) is used, which is synthesized in the following way.

As the polyphenylene ether used in synthesis of modified PPE3, a polyphenylene ether described below is used. This polyphenylene ether is synthesized in the same manner as in the synthesis of modified PPE-1 except that the following conditions are adopted.

The polyphenylene ether used is SA90 manufactured by SABIC Innovative Plastics, having a number of terminal hydroxy groups of 2 and a weight average molecular weight, Mw, of 1700.

The reaction between the polyphenylene ether and chloromethylstyrene is conducted in the same manner as in the synthesis of modified PPE-1 except that 200 g of the polyphenylene ether, 30 g of CMS, and 1.227 g of tetra-n-butylammonium bromide as a phase-transfer catalyst are used and instead of the aqueous sodium hydroxide solution ((10 g of sodium hydroxide)/(10 g of water)), an aqueous sodium hydroxide solution ((20 g of sodium hydroxide)/(20 g of water)) is used.

The resulting solid is subjected to 1H-NMR analysis (400 MHz, CDCl3, TMS). In the NMR analysis, a peak from 5 ppm to 7 ppm attributable to an ethenylbenzyl group was observed. From this result, the solid thus obtained can be identified as a modified polyphenylene ether having a vinylbenzyl group as the substituent within the molecule, or specifically as ethenylbenzyl polyphenylene ether.

The number of terminal functional groups in the modified polyphenylene ether is measured in the same manner as above. The number of terminal functional groups was 2.

The intrinsic viscosity (IV) of the modified polyphenylene ether in methylene chloride at 25° C. is measured in the same manner as above. The intrinsic viscosity (IV) of the modified polyphenylene ether was 0.086 dl/g.

The Mw of the modified polyphenylene ether is measured in the same manner as above. The Mw was 1900.

### (Crosslinking Agent)

As TAIC (triallyl isocyanurate), TAIC manufactured by Nippon Kasei Chemical Company Limited is used. TAIC is a monomer and in a liquid state.

As DVB (divinylbenzene), DVB-810 manufactured by NIPPON STEEL & SUMITOMO METAL CORPORATION is used. DVB is a monomer and in a liquid state.

As DAP (diallyl phthalate), a Daiso chip monomer manufactured by DAISO Co., Ltd. is used. DAP is a monomer and in a liquid state.

### (Inorganic Filler, Metal Oxide)

As a spherical silica 1, SO25R manufactured by Admatechs Company Limited is used. The spherical silica 1 has an average particle diameter of 0.5 μm.

As crushed silica, MC4000 manufactured by Admatechs Company Limited is used.

As a spherical silica 2, ST7010-3 manufactured by NIPPON STEEL & SUMIKIN MATERIALS CO., LTD., Micron Company is used. The spherical silica 2 has an average particle diameter of 9.7 μm.

### (Inorganic Filler, Metal Hydroxide)

As aluminum hydroxide, CL303M manufactured by Sumitomo Chemical Company, Limited is used.

### (Dispersant)

As dispersant 1, a dispersant containing a phosphate group and an imidazoline group is used. Specifically, BYK-W969 manufactured by BYK Japan KK is used. Dispersant 1 has an acid value (in terms of the solid content) of 75 mg KOH/g and an amine value (in terms of the solid content) of 75 mg KOH/g.

As dispersant 2, a dispersant containing a carboxy group and an amino group is used. Specifically, BYK-W966 manufactured by BYK Japan KK is used. Dispersant 2 has an acid value (in terms of the solid content) of 50 mg KOH/g and an amine value (in terms of the solid content) of 37 mg KOH/g.

As dispersant 3, a dispersant containing a phosphate group and an alkylol ammonium salt group is used. Specifically, DISPERBYK-180 manufactured by BYK Japan KK is used. Dispersant 3 has an acid value (in terms of the solid content) of 116 mg KOH/g and an amine value (in terms of the solid content) of 116 mg KOH/g.

As dispersant 4, a dispersant containing a copolymer having a phosphate group is used. Specifically, BYK-W9010 manufactured by BYK Japan KK is used. Dispersant 4 has an acid value of 129 mg KOH/g.

As dispersant 5, a dispersant containing a metal salt of a phosphate group is used. Specifically, BYK-W903 manufactured by BYK Japan KK is used.

### (Reaction Initiator)

As a peroxide, 1,3-bis(butylperoxyisopropyl)benzene is used. Specifically, PERBUTYL® P manufactured by NOF Corporation is used.

### [Method for Preparation]

Components other than the initiator in the proportion shown in Tables 1 to 3 are added to toluene in an amount that achieves a solid concentration of 60% by mass, followed by mixing. The resulting mixture is heated to 80° C. and stirred at 80° C. for 60 minutes. After stirring, the mixture is cooled to 40° C. and thereto, the reaction initiator is added in the proportion shown in Tables 1 to 3. Thus, a curable composition in a varnish form (varnish) is obtained.

Glass cloth is impregnated with the resulting varnish, and the resultant was heated and dried at a temperature from 100° C. to 160° C. for about 2 minutes to about 8 minutes. Thus, a prepreg was obtained. The glass cloth is #2116, WEA116E, or E-glass, all manufactured by NITTO BOSEKI CO., LTD., having a thickness of 0.1 mm. In the impregnation, the content of the organic components in the radically polymerizable compound and the like is about 50% by mass.

Six pieces of the resulting prepreg are laminated together and to the either plane of the laminate, a piece of copper foil having a thickness of 35 μm is disposed. The resultant is heated and pressurized under conditions of a temperature of 200° C., a duration of 2 hours, and a pressure of 3 MPa. By this heating and pressurization, a copper-foil-clad laminate (metal-foil-clad laminate) having copper foil adhered to either plane and having a thickness of about 0.8 mm is obtained. The resulting metal-foil-clad laminate was used as a substrate for evaluation.

The prepreg and the substrate for evaluation thus prepared were evaluated by the following method.

### [Formability (Void)]

The copper foil on either plane of the substrate for evaluation is made into a grid-shape pattern that has a remaining-copper rate of 50%. Thus, a wiring is formed. To either plane of the substrate with the wiring formed thereon, a single piece of the prepreg is laminated. The resulting laminate is heated and pressurized under the same conditions as those in production of the copper-foil-clad laminate. When the resulting laminate (laminate for evaluation) has the gaps between wiring traces sufficiently filled with prepreg resin or the like with no void being formed, the laminate is evaluated as “OK”. In other words, when no void is observed between wiring traces, the laminate is evaluated as “OK”. On the other hand, when the gaps between wiring traces are not sufficiently filled with prepreg resin or the like and voids are observed, the laminate is evaluated as “NG”.

### [Formability (Resin Separation)]

The copper foil on both planes of the substrate for evaluation is removed by etching, and the resulting unclad board is subjected to observation. When no seeping of the organic components, which are components of the cured product other than the inorganic filler, is observed near the edges of the unclad board, the unclad board is evaluated as “OK”. When resin separation is observed, the unclad board is evaluated as “NG”. Seeping of the organic components means resin separation.

### [Glass Transition Temperature (Tg)]

The Tg of the unclad board is measured with a viscoelasticity spectrometer “DMS100” manufactured by Seiko Instruments Inc. The flexural modulus is measured by dynamic viscoelasticity measurement (DMA) at a frequency of 10 Hz while the temperature is raised from room temperature to 280° C. at a rate of 5° C./minute, and the temperature at which the value tan δ reaches its highest value is determined as the Tg. When the Tg is not observed, in such a case as when the unclad board is highly amorphous, the mark “-” is shown in the tables.

### [Thermal Expansion]

The thermal expansion of the unclad board is measured with a thermomechanical analyzer “TMA/SS7100” manufactured by Hitachi High-Tech Science Corporation on a compression mode. The load upon compression is −9.8 mN. The change in volume of the unclad board in the thickness direction is measured upon heating and raising the temperature to 260° C. at a rate of 20° C./minute followed by cooling to room temperature, the volume change thus measured being regarded as the volume change 1, and also upon raising temperature from 50° C. to 260° C. at a rate of 10° C./minute, the volume change thus measured being regarded as the volume change 2. These values of volume change are used to calculate thermal expansion (%).

### [Dielectric Properties (Dielectric Constant and Dissipation Factor)]

The dielectric constant and the dissipation factor of the substrate for evaluation at 10 GHz are measured by cavity resonator perturbation. Specifically, a network analyzer is used to measure the dielectric constant and the dissipation factor of the substrate for evaluation, at 10 GHz. Specifically, a network analyzer N5230A manufactured by Agilent Technologies is used.

### [Copper-Foil Adhesion Strength]

Peel strength, which is the strength measured upon copper foil being peeled off the insulating layer of the copper-foil-clad laminate, is measured in conformity with JIS C6481. A pattern having a width of 10 mm and a length of 100 mm is formed, which is then peeled with a tensile tester at a rate of 50 mm/minute. The peel strength during pealing is measured. The peel strength is defined as the copper-foil adhesion strength. The unit of measurement is kN/m.

### [Post-PCT Solder Heat Resistance]

Post-PCT solder heat resistance (moisture absorption solder heat resistance) is measured by a method in conformity with JIS C 6481. Specifically, three samples of the substrate for evaluation are each subjected to a pressure cooker test (PCT) at 121° C. and 2 atmospheric pressure (0.2 MPa) for 6 hours, during which each sample is immersed in a solder bath at 288° C. for 20 seconds. After immersion, the sample is visually observed for measling or swelling, for example. When no measling or swelling is observed, the sample is evaluated as “OK”. When measling or swelling is observed, the sample is evaluated as “NG”.

### [Post-PCT Moisture Absorption]

Moisture absorption (%) of the substrate for evaluation after PCT is measured.

Evaluation results are shown in Tables 1 to 3.

TABLE 1

| | | | | Example | | | | | | | |
|---|---|---|---|---|---|---|---|---|---|---|---|
| | | | | 1 | 2 | 3 | 4 | 5 | 6 | 7 | 8 |
| Composition | Radically | Polybutadiene | | 100 | — | — | — | — | — | — | — |
| (parts by | polymerizable | Butadiene-styrene | | — | 100 | — | — | — | — | — | — |
| mass) | compound | copolymer | | | | | | | | | |
| | | Modified PPE 1 | | — | — | 70 | — | — | — | — | — |
| | | Modified PPE 2 | | — | — | — | 60 | — | 70 | 60 | 60 |
| | | Modified PPE 3 | | — | — | — | — | 70 | — | — | — |
| | Crosslinking | TAIC | | — | — | 30 | 40 | — | — | 40 | 40 |
| | agent | DVB | | — | — | — | — | 30 | — | — | — |
| | | DAP | | — | — | — | — | — | 30 | — | — |
| | Inorganic | Metal oxide | Spherical | 200 | 200 | 200 | 200 | 200 | 200 | 200 | 200 |
| | filler | | silica 1 | | | | | | | | |
| | Dispersant | Dispersant 1 | | 2 | 2 | 2 | 2 | 2 | 2 | — | — |
| | | Dispersant 2 | | — | — | — | — | — | — | 2 | — |
| | | Dispersant 3 | | — | — | — | — | — | — | — | 2 |
| | | Dispersant 4 | | — | — | — | — | — | — | — | — |
| | | Dispersant 5 | | — | — | — | — | — | — | — | — |
| | Reaction | Peroxide | PERBUTYL | 2 | 2 | 2 | 2 | 2 | 2 | 2 | 2 |
| | initiator | | P | | | | | | | | |
| Evaluation | Prepreg | Formability | Void | OK | OK | OK | OK | OK | OK | OK | OK |
| | | | Resin | OK | OK | OK | OK | OK | OK | OK | OK |
| | | | separation | | | | | | | | |

| | | | | | | | | | |
|---|---|---|---|---|---|---|---|---|---|
| | Tg (° C.) | — | — | 200 | 240 | 220 | 220 | 240 | 240 |
| Copper-clad | Thermal expansion (%) | 1.3 | 1.2 | 1.8 | 1.5 | 1.6 | 1.6 | 1.5 | 1.5 |
| laminate | Dielectric constant | 3.8 | 3.8 | 3.9 | 3.9 | 3.9 | 3.9 | 3.9 | 3.9 |
| | Dissipation factor | 0.004 | 0.004 | 0.005 | 0.005 | 0.005 | 0.005 | 0.005 | 0.005 |
| | Copper-foil adhesion | 0.6 | 0.6 | 0.4 | 0.5 | 0.5 | 0.5 | 0.5 | 0.5 |
| | strength (kN/m) | | | | | | | | |
| | Post-PCT solder heat | OK | OK | OK | OK | OK | OK | OK | OK |
| | resistance | | | | | | | | |
| | Post-PCT moisture | 0.3 | 0.3 | 0.4 | 0.4 | 0.4 | 0.4 | 0.4 | 0.4 |
| | absorption (%) | | | | | | | | |

| | | | | Comparative Example | | | |
|---|---|---|---|---|---|---|---|
| | | | | 1 | 2 | 3 | 4 |
| Composition | Radically | Polybutadiene | | — | — | — | — |
| (parts by | polymerizable | Butadiene-styrene | | — | — | — | — |
| mass) | compound | copolymer | | | | | |
| | | Modified PPE 1 | | — | — | — | — |
| | | Modified PPE 2 | | 60 | 50 | 60 | 60 |
| | | Modified PPE 3 | | — | — | — | — |
| | Crosslinking | TAIC | | 40 | 50 | 40 | 40 |
| | agent | DVB | | — | — | — | — |
| | | DAP | | — | — | — | — |
| | Inorganic | Metal oxide | Spherical | 200 | 200 | 200 | 200 |
| | filler | | silica 1 | | | | |
| | Dispersant | Dispersant 1 | | — | — | — | — |
| | | Dispersant 2 | | — | — | — | — |
| | | Dispersant 3 | | — | — | — | — |
| | | Dispersant 4 | | — | — | 2 | — |
| | | Dispersant 5 | | — | — | — | 2 |
| | Reaction | Peroxide | PERBUTYL | 2 | 2 | 2 | 2 |
| | initiator | | P | | | | |
| Evaluation | Prepreg | Formability | Void | NG | OK | OK | NG |
| | | | Resin | OK | NG | OK | OK |
| | | | separation | | | | |

| | | | | | |
|---|---|---|---|---|---|
| | Tg (° C.) | 240 | 230 | 220 | 240 |
| Copper-clad | Thermal expansion (%) | 1.5 | 1.6 | 1.6 | 1.5 |
| laminate | Dielectric constant | 3.9 | 3.9 | 3.9 | 3.9 |
| | Dissipation factor | 0.005 | 0.005 | 0.006 | 0.005 |
| | Copper-foil adhesion | 0.5 | 0.4 | 0.2 | 0.5 |
| | strength (kN/m) | | | | |
| | Post-PCT solder heat | OK | OK | OK | OK |
| | resistance | | | | |
| | Post-PCT moisture | 0.3 | 0.3 | 0.5 | 0.4 |
| | absorption (%) | | | | |

TABLE 2

| | | | | Example | | | | | | Comparative Example | | |
|---|---|---|---|---|---|---|---|---|---|---|---|---|
| | | | | 4 | 9 | 10 | 11 | 12 | 13 | 5 | 6 | 7 |
| Composition | Radically | Modified PPE2 | | 60 | 60 | 60 | 60 | 60 | 60 | 60 | 60 | 60 |
| (parts by | polymerizable | | | | | | | | | | | |
| mass) | compound | | | | | | | | | | | |
| | Crosslinking | TAIC | | 40 | 40 | 40 | 40 | 40 | 40 | 40 | 40 | 40 |
| | agent | | | | | | | | | | | |
| | Inorganic | Metal oxide | Spherical | 200 | 90 | 400 | — | — | 160 | 50 | 450 | 140 |
| | filler | | silica 1 | | | | | | | | | |
| | | | Crushed | — | — | — | — | 100 | — | — | — | — |
| | | | silica | | | | | | | | | |
| | | | Spherical | — | — | — | 200 | — | — | — | — | — |
| | | | silica 2 | | | | | | | | | |
| | | Metal | Aluminum | — | — | — | — | — | 40 | — | — | 60 |
| | | hydroxide | hydroxide | | | | | | | | | |
| | Dispersant | Dispersant 1 | | 2 | 1 | 4 | 2 | 1 | 2 | 0.5 | 4.5 | 2 |
| | Reaction | Peroxide | PERBUTYL | 2 | 2 | 2 | 2 | 2 | 2 | 2 | 2 | 2 |
| | initiator | | P | | | | | | | | | |
| Evaluation | Prepreg | Formability | Void | OK | OK | OK | OK | OK | OK | OK | NG | OK |
| | | | Resin | OK | OK | OK | OK | OK | OK | OK | NG | OK |
| | | | separation | | | | | | | | | |

| | | | | | | | | | | |
|---|---|---|---|---|---|---|---|---|---|---|
| | Tg (° C.) | 240 | 240 | 240 | 240 | 240 | 240 | 240 | 240 | 240 |
| Copper-clad | Thermal expansion (%) | 1.5 | 2 | 1 | 1.5 | 2 | 1.5 | 2.5 | 0.8 | 1.5 |
| laminate | Dielectric constant | 3.9 | 3.8 | 4.1 | 3.9 | 3.8 | 4.1 | 3.7 | 4.2 | 4.2 |
| | Dissipation factor | 0.005 | 0.006 | 0.005 | 0.005 | 0.006 | 0.005 | 0.006 | 0.005 | 0.005 |
| | Cooper-foil adhesion | 0.5 | 0.6 | 0.4 | 0.5 | 0.6 | 0.4 | 0.7 | 0.3 | 0.3 |
| | strength (kN/m) | | | | | | | | | |
| | Post-PCT solder heat | OK | OK | OK | OK | OK | OK | OK | OK | NG |
| | resistance | | | | | | | | | |
| | Post-PCT moisture | 0.4 | 0.3 | 0.5 | 0.4 | 0.3 | 0.4 | 0.2 | 0.6 | 0.6 |
| | absorption (%) | | | | | | | | | |

TABLE 3

| | | | | Example | | | Comparative Example | |
|---|---|---|---|---|---|---|---|---|
| | | | | 4 | 14 | 15 | 1 | 2 |
| Composition | Radically | Modified PPE2 | | 60 | 60 | 60 | 60 | 50 |
| (parts by | polymerizable | | | | | | | |
| mass) | compound | | | | | | | |
| | Crosslinking | TAIC | | 40 | 40 | 40 | 40 | 50 |
| | agent | | | | | | | |
| | Inorganic | Metal oxide | Spherical | 200 | 200 | 200 | 200 | 200 |
| | filler | | silica 1 | | | | | |
| | Dispersant | Dispersant 1 | | 2 | 0.2 | 10 | — | — |
| | Reaction | Peroxide | PERBUTYL | 2 | 2 | 2 | 2 | 2 |
| | initiator | | P | | | | | |
| Evaluation | Prepreg | Formability | Void | OK | OK | OK | NG | OK |
| | | | Resin | OK | OK | OK | OK | NG |
| | | | separation | | | | | |

| | | | | | | |
|---|---|---|---|---|---|---|
| | Tg (° C.) | 240 | 240 | 220 | 240 | 230 |
| Copper-clad | Thermal expansion (%) | 1.5 | 1.5 | 1.5 | 1.5 | 1.6 |
| laminate | Dielectric constant | 3.9 | 3.9 | 4 | 3.9 | 3.9 |
| | Dissipation factor | 0.005 | 0.005 | 0.006 | 0.005 | 0.005 |
| | Copper-foil adhesion | 0.5 | 0.5 | 0.4 | 0.5 | 0.4 |
| | strength (kN/m) | | | | | |
| | Post-PCT solder heat | OK | OK | OK | OK | OK |
| | resistance | | | | | |
| | Post-PCT moisture | 0.4 | 0.3 | 0.7 | 0.3 | 0.3 |
| | absorption (%) | | | | | |

As shown in Tables 1 to 3, when a dispersant containing an acidic group and a basic group is contained (Examples 1 to 15), the resulting copper-foil-clad laminate has a cured product that has excellent dielectric properties, excellent heat resistance, and low thermal expansion. Each of the curable compositions of Examples 1 to 15, which is a curable composition that cured by radical polymerization, includes a relatively high amount of the inorganic filler and when used, an excellent copper-foil-clad laminate as described above is obtained. It is also shown that the prepreg including the curable composition has excellent formability. The copper-foil-clad laminates produced by using the curable compositions of Examples 1 to 15 have high copper-foil adhesion strength.

In contrast to the examples, when the curable composition including no dispersant (Comparative Examples 1 and 2) was used, the resulting prepreg had poor formability as shown in Table 1. When the curable composition including a dispersant containing an acidic group but no basic group (Comparative Examples 3 and 4) was used, the resulting prepreg had poor formability or low copper-foil adhesion strength.

As shown in Table 2, when the content of the inorganic filler was lower than 80 parts by mass relative to the amount of the organic components of 100 parts by mass (Comparative Example 5), thermal expansion was not sufficiently lowered. When the content of the inorganic filler was higher than 400 parts by mass relative to the amount of the organic components of 100 parts by mass (Comparative Example 6), the formability of the prepreg was poor despite that fact that a dispersant containing an acidic group and a basic group was contained. When the content of the metal oxide was lower than 80 parts by mass relative to the amount of the inorganic filler of 100 parts by mass (Comparative Example 7), heat resistance and dielectric properties were poor. A reason for this phenomenon is considered that when the relative content of the metal oxide in the inorganic filler is low, the relative content of the metal hydroxide in the inorganic filler is high.

Table 3 indicates that when the content of the dispersant is between 0.1 part by mass and 5 parts by mass (inclusive) relative to the amount of the inorganic filler of 100 parts by mass (Examples 4, 14, and 15), the effects of the dispersant are sufficiently exhibited. In other words, it is indicated that the resulting copper-foil-clad laminate has a cured product that has excellent dielectric properties, excellent heat resistance, and low thermal expansion.

As described above, it has been proven that the curable composition according to the present exemplary embodiment is a curable composition that can suitably produce a cured product having excellent dielectric properties, excellent heat resistance, and low thermal expansion.

### INDUSTRIAL APPLICABILITY

According to the present disclosure, a curable composition that can suitably produce a cured product having excellent dielectric properties, excellent heat resistance, and low thermal expansion is provided and, therefore, the present disclosure is useful.

### REFERENCE MARKS IN THE DRAWINGS

1: prepreg
2: curable composition
3: fibrous base material
11: metal-clad laminate
12, 32: insulating layer
13: metal layer
14: wiring
21: printed wiring board
31: metal foil with resin

1. A curable composition, comprising:
a radically polymerizable compound containing an unsaturated bond within a molecule;
an inorganic filler containing a metal oxide; and
a dispersant containing an acidic group and a basic group; wherein:
a content of the metal oxide is between 80 parts by mass and 100 parts by mass (inclusive) relative to an amount of the inorganic filler of 100 parts by mass,
components of the curable composition other than the inorganic filler are organic components,
a content of the inorganic filler is between 80 parts by mass and 400 parts by mass (inclusive) relative to an amount of the organic components of 100 parts by mass,
a content of the dispersant is between 0.1 part by mass and 5 parts by mass (inclusive) relative to the amount of the inorganic filler of 100 parts by mass.

2. The curable composition according to claim 1, wherein:
the acidic group is at least one kind selected from the group consisting of a phosphate group, a carboxy group, a hydroxy group, and a sulfo group, and
the basic group is at least one kind selected from the group consisting of an imidazoline group, an amino group, an ammonium salt group, a pyrrole group, an imidazole group, a benzimidazole group, a pyrazole group, a pyridine group, a pyrimidine group, a pyrazine group, a pyrrolidine group, a piperidine group, a piperazine group, an indole group, an indoline group, a purine group, a quinoline group, an isoquinoline group, a quinuclidine group, and a triazine group.

3. The curable composition according to claim 1, wherein the dispersant has an acid value between 30 mg KOH/g and 150 mg KOH/g (inclusive) in terms of solid content and an amine value between 30 mg KOH/g and 150 mg KOH/g (inclusive) in terms of solid content.

4. The curable composition according to claim 1, further comprising a crosslinking agent, the crosslinking agent containing an unsaturated bond within a molecule.

5. The curable composition according to claim 1, wherein the radically polymerizable compound is a modified polyphenylene ether, the modified polyphenylene ether having a terminal functional group containing an unsaturated bond.

6. The curable composition according to claim 5, wherein:
a weight average molecular weight of the modified polyphenylene ether is between 500 and 5000 (inclusive), and
a number of functional groups per molecule of the modified polyphenylene ether is between 1 and 5 (inclusive) on average.

7. The curable composition according to claim 1, wherein the metal oxide is spherical silica.

8. The curable composition according to claim 1, further comprising a reaction initiator.

9. A prepreg, comprising:
the curable composition according to claim 1; and
a fibrous base material impregnated with the curable composition.

10. A metal foil with resin, comprising:
a metal layer; and
an insulating layer disposed on the metal layer;
the insulating layer containing the curable composition according to claim 1 in an uncured state.

11. A metal-clad laminate, comprising:
an insulating layer containing a cured product of the curable composition according to claim 1; and
a metal layer disposed on the insulating layer.

12. A printed wiring board, comprising:
an insulating layer containing a cured product of the curable composition according to claim 1; and
wiring disposed on the insulating layer.
